(19) United States
(12) Patent Application Publication
(10) Pub. No.: US 2014/0273318 A1
(43) Pub. Date: Sep. 18, 2014

(54) METHOD OF FORMING METALLIC BONDING LAYER AND METHOD OF MANUFACTURING SEMICONDUCTOR LIGHT EMITTING DEVICE THEREWITH

(71) Applicant: SAMSUNG ELECTRONICS CO., LTD., Suwon-si (KR)

(72) Inventors: Yung Ho RYU, Suwon-si (KR); Jong Hoon LIM, Suwon-si (KR); Sung Joon KIM, Suwon-si (KR); Tae Hun KIM, Anyang-si (KR); Gyeong Seon PARK, Seoul (KR); Myong Soo CHO, Yongin-si, Gyeonggi-do (KR)

(73) Assignee: SAMSUNG ELECTRONICS CO., LTD., Suwon-si (KR)

(21) Appl. No.: 14/207,466

(22) Filed: Mar. 12, 2014

(30) Foreign Application Priority Data
Mar. 15, 2013 (KR) 10-2013-0028185

(51) Int. Cl. H01L 33/00; B23K 1/00

(52) U.S. Cl. CPC H01L 33/005; B23K 1/0006
USPC 438/26; 228/198

(57) ABSTRACT

A method of forming a metal bonding layer includes forming a first bonding metal layer and a second bonding metal layer on surfaces of first and second bonding target objects, respectively. The second bonding target object is disposed on the first bonding target object to allow the first and second bonding metal layers to face each other. A eutectic metal bonding layer is formed through a reaction between the first and second bonding metal layers. At least one of the first and second bonding metal layers includes a reaction delaying layer formed of a metal for delaying the reaction between the first and second bonding metal layers.

### CROSS-REFERENCE TO RELATED APPLICATION

This application claims priority to, and benefit of, Korean Patent Application No. 10-2013-0028185 filed on Mar. 15, 2013, with the Korean Intellectual Property Office, the entire contents of which are hereby incorporated by reference.

### TECHNICAL FIELD

The present disclosure relates to a method of forming a metallic bonding layer, and more particularly, to a method of manufacturing a semiconductor light emitting device therewith.

### BACKGROUND

A technology of bonding a target object such as an electronic device to another object such as a substrate by using a bonding metal has been widely used. In particular, when manufacturing an electronic device such as a semiconductor light emitting device and transferring the manufactured electronic device to a different substrate, a bonding technology of using a eutectic metal has been used to transfer the manufactured electronic device to a permanent substrate.

However, unnecessary voids may be generated within a eutectic metal bonding layer formed by a reaction between bonding metals, thereby deteriorating bonding strength. In particular, a problem as described above may easily occur when a bonding surface is uneven, and thus, it may become a main causative factor in generating a defect in bonding between target objects.

### SUMMARY

The present disclosure provides a method of forming a metallic bonding layer having improved connection reliability to suppress the generation of voids and maintain solid bonding at the time of bonding target objects, and a method of manufacturing a semiconductor light emitting device using the metallic bonding layer formed thereby.

An aspect of the inventive concept relates to a method of forming a metallic bonding layer, including forming a first bonding metal layer and a second bonding metal layer on surfaces of first and second bonding target objects, respectively. The second bonding target object is disposed on the first bonding target object to allow the first and second bonding metal layers to face each other. A eutectic metal bonding layer is formed through a reaction between the first and second bonding metal layers. At least one of the first and second bonding metal layers includes a reaction delaying layer formed of a metal for delaying the reaction between the first and second bonding metal layers.

The at least one of the first and second bonding metal layers may include a metal selected from the group consisting of tin (Sn), indium (In), zinc (Zn), bismuth (Bi), lead (Pb), nickel (Ni), gold (Au), platinum (Pt), copper (Cu), cobalt (Co), and an alloy thereof.

In this case, the reaction delaying layer may include a metal selected from the group consisting of titanium (Ti), tungsten (W), chromium (Cr), tantalum (Ta), and an alloy thereof. The reaction delaying layer may have a thickness of 10 Å to 1000 Å.

The at least one of the first and second bonding metal layers may include a first reaction layer formed on one surface of the first or second bonding target object and containing at least one of nickel (Ni), platinum (Pt), gold (Au), copper (Cu) and cobalt (Co) and a second reaction layer formed on the first reaction layer, reacting with a metal of the first reaction layer to provide a eutectic metal, and containing a metal selected from the group consisting of tin (Sn), indium (In), zinc (Zn), bismuth (Bi), gold (Au), cobalt (Co), and an alloy thereof, and in this case, the reaction delaying layer may be located between the first reaction layer and the second reaction layer.

The at least one of the first and second bonding metal layers may further include a cap layer formed on the second reaction layer and containing at least one of platinum (pt) and lead (pb).

The surfaces of the first and second bonding target objects, on which the first bonding metal layer and the second bonding metal layer are formed, respectively, may be uneven surfaces. The surfaces, as bonding surfaces, may have a step portion or a concave-convex portion.

Another aspect of the inventive concept encompasses a method of manufacturing a semiconductor light emitting device, including preparing a light emitting laminate including a first conductive semiconductor layer, an active layer, and a second conductive semiconductor layer sequentially formed on a temporary substrate. A first bonding metal layer is formed on the light emitting laminate and a second bonding metal layer is formed on a permanent substrate. The light emitting laminate is disposed on the permanent substrate to allow the first and second bonding metal layers to contact each other. A eutectic metal bonding layer is formed through a reaction between the first and second bonding metal layers to bond the light emitting laminate to the permanent substrate. At least one of the first and second bonding metal layers includes a reaction delaying layer formed of a metal for delaying the reaction between the first and second bonding metal layers.

The permanent substrate maybe a conductive substrate. The method of manufacturing a semiconductor light emitting device may further include removing the temporary substrate, a semiconductor growth substrate, after the forming of the eutectic metal bonding layer.

Still another aspect of the inventive concept relates to a method of forming a metal bonding layer, including forming a first bonding metal layer and a second bonding metal layer on surfaces of first and second bonding target objects, respectively. The first and second bonding metal layers include first and second reaction delaying layers formed of a metal, respectively. A first mixture layer, including a eutectic metal resulting from a reaction between the first and second bonding metal layers, is formed. A first residual reaction delaying layer and a second residual reaction delaying layer are formed. A first residual reaction delaying layer and a second residual reaction delaying layer are positioned in a vicinity of the first mixture layer through a reaction between the first and second bonding metal layers.

The method may include forming a second mixture layer at an edge of the first residual reaction delaying layer and forming a third mixture layer at an edge of the second residual reaction delaying layer.

The eutectic metal may be formed of NiSn or NiSnAu.

The reaction delaying layer may include a metal selected from the group consisting of titanium (Ti), tungsten (W), chromium (Cr), tantalum (Ta), and an alloy thereof.

The first and second residual reaction delaying layers maybe formed of the same material as a material of the reaction delaying layer. The first and second residual reaction delaying layers may be warped or partially disconnected.

### BRIEF DESCRIPTION OF THE DRAWINGS

The above and other aspects, features and other advantages will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIGS. 1A and 1B are cross-sectional views illustrating the steps of a method of forming a metallic bonding layer according to an embodiment of the present inventive concept.

FIGS. 2 and 3 are images provided by scanning cross sections of metallic bonding layers formed according to embodiment 1 of the present inventive concept and a comparative example.

FIG. 4 is an image captured using a scanning electron microscope to confirm a distribution of a reaction layer in the metallic bonding layer formed according to embodiment 1.

FIGS. 5A to 5C are images obtained by scanning a cross section of a metallic bonding layer according to embodiment 2 (a change in the metallic bonding layer depending on a thickness of a reaction delaying layer) of the present inventive concept.

FIG. 6 is a cross-sectional view of a eutectic metal layer used in a method of forming a metal bonding layer according to an embodiment of the present inventive concept.

FIGS. 7A to 7C are cross-sectional views illustrating various examples of a metallic bonding layer formed due to a reaction of a metal bonding layer of FIG. 6.

FIG. 8 is a cross-sectional view of a metal bonding layer used in a method of forming a metallic bonding layer according to another embodiment of the present inventive concept.

FIGS. 9A to 9D are cross-sectional views illustrating various examples of a metallic bonding layer formed due to a reaction of a metal bonding layer of FIG. 8.

FIG. 10 is a cross-sectional view of a eutectic metal layer used in a method of forming a metallic bonding layer according to another embodiment of the present inventive concept.

FIGS. 11A and 11B are cross-sectional views illustrating various examples of a metal bonding layer formed through a reaction of a metallic bonding layer of FIG. 10.

FIG. 12 is a cross-sectional view of a eutectic metal layer used in a method of forming a metallic bonding layer according to another embodiment of the present inventive concept.

FIGS. 13A to 13C are cross-sectional views illustrating various examples of a metal bonding layer formed through a reaction of a metallic bonding layer of FIG. 12.

FIGS. 14A to 14D are cross-sectional views illustrating example steps of a method of manufacturing a semiconductor light emitting device according to another embodiment of the present inventive concept.

FIGS. 15A and 15B are a plan view and a side cross-sectional view illustrating another example of the semiconductor light emitting device fabricated by the method of manufacturing a semiconductor light emitting device according to an embodiment of the present inventive concept.

### DETAILED DESCRIPTION

Embodiments of the present inventive concept will now be described in detail with reference to the accompanying drawings.

Embodiments of the present inventive concept may, however, be embodied in many different forms and should not be construed as being limited to embodiments set forth herein. Rather, these embodiments of the present inventive concept are provided so that this disclosure will be thorough and complete, and will fully convey the scope of the inventive concept to those skilled in the art.

FIGS. 1A and 1B are cross-sectional views illustrating a method of forming a metallic bonding layer according to an embodiment of the present inventive concept.

With reference to FIG. 1A, as bonding target objects, first and second substrates 11 and 21 have respective surfaces on which first and second bonding metal layers 12 and 22 are formed respectively.

In the embodiment of FIG. 1A, although a substrate is provided as the bonding target object, electronic devices such as semiconductor light emitting devices and memory devices, as well as a simple substrate and a substrate having electronic circuits performing specific functions, implemented thereon, may be provided as bonding objects.

The respective first and second bonding metal layers 12 and 22 may include a metal (including an alloy) thereof selected from tin (Sn), indium (In), zinc (Zn), bismuth (Bi), lead (Pb), nickel (Ni), gold (Au), platinum (Pt), copper (Cu), cobalt (Co) or an alloy thereof.

In detail, as shown in FIG. 1A, the first bonding metal layer 12 may include a first reaction layer 12a formed on one surface of the first substrate 11, and a second reaction layer 12b formed on the first reaction layer 12a. Similarly, the second bonding metal layer 22 may include a first reaction layer 22a formed on one surface of the second substrate 21 and a second reaction layer 22b formed on the first reaction layer 22a.

The two reaction layers 12a and 12b of the first bonding metal layer 12 react with each other and the two reaction layers 22a and 22b of the second bonding metal layer 22 react with each other, to form a eutectic metal. Although not particularly limited, the second reaction layer 12b of the first bonding metal layer 12 may include a metal (including an alloy) having a relatively high diffusion coefficient as compared with the first reaction layer 12a, and the first reaction layer 12a of the first bonding metal layer 12 may serve to maintain adhesion between the first substrate 11 and the first bonding metal layer 12. Similarly, the second reaction layer 22b of the second bonding metal layer 22 may include a metal (including an alloy) having a relatively high diffusion coefficient as compared with the first reaction layer 22a, and the first reaction layer 22a of the second bonding metal layer 22 may serve to maintain adhesion between the second substrate 21 and the second bonding metal layer 22.

For example, as the first reaction layers 12a and 22a, a metal of at least one of Ni, Pt and Cu may be included therein. The respective second reaction layers 12b and 22b may include a metal selected from tin (Sn), indium (In), zinc (Zn), bismuth (Bi), gold (Au), cobalt (Co), or an alloy thereof,

In the embodiment of FIG. 1A, the first bonding metal layer 12 may include a reaction delaying layer 15 for delaying a reaction generated between the first and second reaction layers 12a and 12b during a bonding process. That is, the reaction delaying layer 15 may serve to suppress fluidity when a metal melted during a bonding process of melting the first and second metal bonding layer 12 and 22 is moved to react with other metals or alloys. As such, the reaction delaying layer 15 may include a metal material having a relatively low diffusion coefficient as compared with a reaction material configuring the first and second bonding metal layers 12 and 22 or having relatively high thermal or chemical stability as compared with surrounding reaction materials.

For example, the reaction delaying layer 15 may include a metal selected from titanium (Ti), tungsten (W), chromium (Cr), tantalum (Ta) or an alloy thereof. The reaction delaying layer 15 may have a thickness of 10 Å to 1000 Å.

As shown in FIG. 1A, the second substrate 21 may be disposed on the first substrate 11 such that the first bonding metal layer 12 and the second bonding metal layer 22 face each other, and conditions of bonding may be applied thereto. For example, a predetermined level of heat may be applied thereto such that the first and second bonding metal layers 12 and 22 are melted.

FIG. 1B illustrates a state in which the first and second substrates 11 and 21 are bonded to each other by a eutectic metal bonding layer EM formed by melting the first and second bonding metal layers 12 and 22.

In the molten state, the second reaction layers 12b and 22b may have relatively high fluidity as compared with the first reaction layers 12a and 22a, and respectively react with the first reaction layers 12a and 22a. As a result, as shown in FIG. 1B, the eutectic metal bonding layer EM may have a eutectic metal layer R including a reaction resultant material between the first reaction layer and the second reaction layer to have relatively high bonding strength. In some cases, residual first reaction layers 12a′ and 22a′ may be present, and such residual first reaction layers 12a′ and 22a′ may serve to maintain bonding force between the first and second substrates 11 and 21.

In the embodiment of FIGS. 1A and 1B, the reaction delaying layer 15 may reduce fluidity of the second reaction layers 12b and 22b for delaying the reaction with the first reaction layers 12a and 22a. As a result, the generation of voids inside the eutectic metal reacting during the delay procedure as described above may be reduced, thereby allowing for a relatively high filling rate therein.

In more detail, molten Sn, SnAu layers, and the like, used as the second reaction layers 12b and 22b may react with different reaction layers (i.e., the first reaction layers 12a and 22a), for example, an Ni layer, a Pt layer, or a Cu layer, to thus form a eutectic metal bonding layer while forming NiSn, NiSnAu, PtSnAu and CuSn phases. Without a reaction delaying layer, e.g., the reaction delaying layer 15, fluidity of the Sn layer, melted during the reaction process described above, may be reduced. Therefore, the Sn layer, the SnAu layer, the NiSn layer, the NiSnAu layer, the PtSnAu layer and the CuSn layer may not fill a step part formed in a bonding surface of a semiconductor layer or a substrate, and thus, voids may be formed in the bonding surface of the semiconductor layer and the substrate. In an embodiment of the present inventive concept, a reaction delaying layer may be formed between two reaction layers to delay a reaction therebetween, thereby securing a sufficient degree of fluidity to realize a relatively high filling rate.

In particular, even when bonding surfaces of first and second substrates of a bonding target object have uneven or rough surfaces, that is, a step structure or a surface having concave-convex portions, the eutectic metal bonding layer EM having an excellent bonding strength through a filling effect using the reaction delay as described above may be obtained.

Hereinafter, operations and effects of the reaction delaying layer according to an embodiment of the present inventive concept will be described with reference to embodiments described below.

### Embodiment 1

Referring to FIG. 2, an Ni layer and an SnAu layer (as a first bonding metal layer) were formed, as respective first and second reaction layers, on an epitaxial layer of a GaN light emitting device A1 having a predetermined step S. Similarly, an Ni layer and an SnAu layer (as a second bonding metal layer) were formed, as respective first and second reaction layers, on a silicon substrate B1. Meanwhile, in the case of the first bonding metal layer, a reaction delaying layer, such as, a Ti layer of 50 nm, was interposed between the Ni layer and the SnAu layer.

Subsequently, heat was applied thereto such that the GaN light emitting device A1 and the silicon substrate B1 were bonded to each other through the first and second bonding metal layers, to thereby form a eutectic metal bonding layer.

### COMPARATIVE EXAMPLE 1

Referring to FIG. 3, in a similar manner to embodiment 1 above, an Ni layer and an SnAu layer (as a first bonding metal layer) were formed, as respective first and second reaction layers, on an epitaxial layer of a GaN light emitting device A2 having a predetermined step S. Similarly, an Ni layer and an SnAu layer (as a second bonding metal layer) were formed, as respective first and second reaction layers, on a silicon substrate B2. Meanwhile, unlike embodiment 1, a reaction delaying layer was not used.

Subsequently, heat was applied thereto such that the GaN light emitting device A2 and the silicon substrate B2 were bonded to each other through the first and second bonding metal layers, to thereby form a eutectic metal bonding layer.

Images obtained by capturing cross sections of the eutectic metal bonding layers formed through embodiment 1 and comparative example 1 are shown in FIGS. 2 and 3, respectively.

As shown in FIG. 2, the eutectic metal bonding layer EM according to embodiment 1 showed a region having a partially generated reaction, and despite that the GaN light emitting device A1 has a step S, voids were not generated in the entire region thereof. Meanwhile, as shown in FIG. 3, in the case of the eutectic metal bonding layer EM according to comparative example 1, a reaction through the reaction layers was generated over a relatively wide region. In particular, it was confirmed that a relatively large void V was generated in a region immediately below the step S of the GaN light emitting device A.

That is, in the case of comparative example 1, the reaction between Ni and SnAu progressed rapidly over a relatively wide region, thereby generating voids in an uneven surface, not yet filled therein, such as the step S, while in the case of embodiment 1, the reaction between Ni and SnAu was delayed by the Ti reaction delaying layer located between the two reaction layers such that even an uneven surface such as the step (S) structure may be maintained with a relatively high fluidity while securing a filling time, whereby the generation of voids may be significantly suppressed.

In this regard, with reference to FIG. 4, it can be confirmed that a relatively small amount of NiSnAu eutectic metal, a reaction resultant material, is present in a region in which the Ti reaction delaying layer is positioned. As such, the Ti reaction delaying layer suppressed the reaction between Ni and SnAu to retain the fluidity for a relatively long time, and as a result, voids were not generated even in indented portions of the GaN light emitting device A1 while obtaining uniform filling therein.

As described above, even in the bonded objects having an uneven surface such as a step structure, the reaction between the metal bonding layers may be delayed using a reaction delaying layer, thereby providing a eutectic metal bonding layer having a relatively high bonding strength due to a relatively high filling rate therein.

In addition, further experimentation, as described in embodiment 2A, embodiment 2B, and comparative example 2 below, was carried out in order to observe a reaction delay effect depending on a thickness of a reaction delaying layer.

### Embodiment 2A

Referring to FIG. 5B, similar to the afore-described embodiment 1, an Ni layer and an SnAu layer (as a first bonding metal layer) were formed, as respective first and second reaction layers, on an epitaxial layer of a GaN light emitting device A4 having a predetermined step S, and in the same manner as the description above, an Ni layer and an SnAu layer (as a second bonding metal layer) were formed, as respective first and second reaction layers, on a silicon substrate B4. Further, a reaction delaying layer, that is, a Ti layer, was interposed between Ni and SnAu of the first bonding metal layer. A thickness of the Ti layer was 50 Å to produce a sample 2A.

Subsequently, heat was applied thereto such that the GaN light emitting device A4 and the silicon substrate B4 were bonded to each other through the first and second bonding metal layers, thereby forming a eutectic metal bonding layer EM4.

### Embodiment 2B

Referring to FIG. 5C, similar to the afore-described embodiment 1, an Ni layer and an SnAu layer (as a first bonding metal layer) were formed, as respective first and second reaction layers, on an epitaxial layer of a GaN light emitting device A5 having a predetermined step S, and in the same manner as the description above, an Ni layer and an SnAu layer (as a second bonding metal layer) were formed, as respective first and second reaction layers, on a silicon substrate B5. Further, a reaction delaying layer, that is, a Ti layer, was interposed between Ni and SnAu of the first bonding metal layer. Unlike embodiment 2A, a thickness of the Ti layer was 300 Å to produce a sample 2B.

Subsequently, heat was applied thereto such that the GaN light emitting device A5 and the silicon substrate B5 were bonded to each other through the first and second bonding metal layers, thereby forming a eutectic metal bonding layer EM5.

### COMPARATIVE EXAMPLE 2

Referring to FIG. 5A, in a similar manner to the above-described embodiments, an Ni layer and an SnAu layer (as a first bonding metal layer) were formed, as respective first and second reaction layers, on an epitaxial layer of a GaN light emitting device A3 having a predetermined step S, and in the same manner as the description above, an Ni layer and an SnAu layer (as a second bonding metal layer) were formed, as respective first and second reaction layers, on a silicon substrate B3. Meanwhile, here, a Ti layer was not used in any cases of the first and second bonding metal layers.

Subsequently, heat was applied thereto such that the GaN light emitting device A3 and the silicon substrate B3 were bonded to each other through the first and second bonding metal layers, thereby forming a eutectic metal bonding layer EM3.

FIGS. 5A to 5C are images obtained by scanning cross sections of eutectic metal bonding layers provided according to comparative example 2, embodiment 2A and embodiment 2B, respectively.

As shown in FIG. 5A, in a case in which a Ti layer is not used (Comparative example 2), it can be seen that a relatively large void V is formed. That is, a bonding strength maybe significantly deteriorated due to such a large void while largely deteriorating device reliability.

Meanwhile, referring to FIGS. 5B and 5C, when the Ti layer has a thickness of 50 Å (embodiment 2A), a relatively very small void V was only found as shown in FIG. 5B, and when the Ti layer has a thickness of 300 Å (embodiment 2B), no any voids were generated as shown in FIG. 5C.

As such, FIGS. 5A-5C shows that as the thickness of the reaction delaying layer, such as the Ti layer, increased, a reaction delay time increased and the filling operation was further facilitated. However, in order to prevent the occurrence of a case in which a reaction delay time excessively increases or a reaction itself is suppressed, a thickness of the reaction delaying layer may be adjusted to be suitable for a metal bonding system. In this regard, the thickness of the reaction delaying layer may not exceed 1000 Å. On the other hand, in order to obtain a reaction delay effect, the reaction delaying layer may have a thickness of at least 10 Å.

Hereinafter, various examples of a metal bonding system using a reaction delaying layer will be described. FIGS. 6 to 13 each illustrate a structure of a eutectic metal bonding layer employing a structure of a metal bonding layer and a material configuring the metal bonding layer.

First, FIG. 6 shows, as a bonding target object, first and second substrates 111 and 121 having respective surfaces on which first and second bonding metal layers 112 and 122 are formed, respectively.

The first bonding metal layer 112 may include a first reaction layer 112a formed on one surface of the first substrate 111 and a second reaction layer 112b formed on the first reaction layer 112a. In a similar manner to the description above, the second bonding metal layer 122 may also include a first reaction layer 122a formed on one surface of the second substrate 121 and a second reaction layer 122b formed on the first reaction layer 122a. In addition, unlike the embodiment illustrated in FIG. 1A, reaction delaying layers 115 and 125 may be included in both of the first and second bonding metal layers 112 and 122. That is, the reaction delaying layers 115 and 125 may be included in the first and second bonding metal layers 112 and 122, respectively.

In the example of FIG. 6, the second reaction layers 112b and 122b may be formed of Sn or AuSn, and the first reaction layers 112a and 122a may be formed of Ni. Besides using Ni, platinum (Pt), gold (Au), copper (Cu) or cobalt (Co) may be used for forming the first reaction layer. The above-mentioned reaction delaying layers 115 and 125 may both include a Ti layer.

As described above, the reaction delaying layers 115 and 125 formed of Ti may secure a sufficient degree of fluidity by delaying a reaction process performed in a bonding procedure such that a desired filling rate is obtained and a bonding system having excellent reliability may be provided. FIGS. 7A to 7C each illustrate a eutectic metal bonding layer (EM) structure obtained by using the first and second bonding metal layers illustrated in FIG. 6.

As shown in FIG. 7A, a eutectic metal bonding layer EM1 may include a mixture layer R11 including a eutectic metal formed of NiSn or NiSn/Sn/NiSn (alternatively, formed of NiSnAu when the first reaction layer is formed of AuSn) in a central region thereof, and Ti layers 115′ and 125′ positioned in the vicinity of the mixture layer R11. Residual Ti layers 115′ and 125′ may be present in a somewhat transformed manner (e.g., a warped or partially disconnected state) in the reaction process. An Ni layer 112a′ may remain between the Ti layer 115′ and the first substrate 111. An Ni layer 122a′ may remain between the Ti layer 125′ and the second substrate 121.

In a different form, as shown in FIG. 7B, a eutectic metal bonding layer EM2 may include a first mixture layer R11 including a eutectic metal formed of NiSn or NiSn/Sn/NiSn (alternatively, formed of NiSnAu when the first reaction layer is formed of AuSn) in a central region thereof, and Ti layers 115′ and 125′ positioned in the vicinity of the first mixture layer R11. In addition, Sn may be diffused on one side, that is, the Ti layer 115′, to form a second mixture layer R12 formed of NiSn or NiAuSn. In the form of bonding system as shown in FIG. 7B, the Ni layers 112a′ and 122′ may also remain in an interface between the first and second substrates 111 and 121.

In a different form of bonding system, as shown in FIG. 7C, a eutectic metal bonding layer EM3 may include a first mixture layer R11 including a eutectic metal formed of NiSn or NiSn/Sn/NiSn (alternatively, formed of NiSnAu when the first reaction layer is formed of AuSn) in a central region thereof. The eutectic metal bonding layer EM3 may also include Ti layers 115′ and 125′ positioned in the vicinity of the first mixture layer R11, and a second mixture layer R12 formed of NiSn or NiAuSn at an edge of the eutectic metal bonding layer EM3, on which an Ni layer barely remains due to an overall reaction of the eutectic metal bonding layer EM3.

As such, even when the same metal bonding layer as shown in FIG. 6 is used, various forms of bonding systems, that is, eutectic metal bonding layers EM, may be provided according to a bonding process actually applied thereto as shown in FIGS. 7A to 7C. On the other hand, the bonding systems shown in FIGS. 7A to 7C may be considered to be serial processes in which reaction processes are performed in sequence as illustrated therein together with diffusion, e.g., in the order of FIGS. 7A, 7B and 7C.

FIG. 8 illustrates another example of a structure having a metal bonding layer.

With reference to FIG. 8, as a bonding target object, first and second substrates 211 and 221 having one surface on which respective first and second bonding metal layers 212 and 222 are formed are shown.

The first bonding metal layer 212 may include a first reaction layer 212a formed on one surface of the first substrate 211 and a second reaction layer 212b, 212c having a dual-layer structure formed on the first reaction layer 212a. In a similar manner thereto, the second bonding metal layer 222 may also include a first reaction layer 222a formed on one surface of the second substrate 221 and a second reaction layer 222b, 222c having a dual-layer structure formed on the first reaction layer 222a.

In the example of FIG. 8, the second reaction layer having the dual-layer structure may be provided such that an Au layer 212c and an Sn layer 212b sequentially stacked and an Au layer 222c and an Sn layer 222b sequentially stacked.

The reaction delaying layers 215 and 225 may be respectively provided with the first and second bonding metal layers 212 and 222. That is, the reaction delaying layer 215 may be formed between the first reaction layer 212a and the Au layer 212c, and the reaction delaying layer 225 may be formed between the first reaction layer 222a and the Au layer 222c.

The first reaction layers 212a and 222a may be formed of Ni. Besides using Ni, as the first reaction layers 212a and 222a, platinum (Pt), gold (Au), copper (Cu) or cobalt (Co) may be used. The reaction delaying layers 215 and 225 may both be formed of a Ti layer. In addition, as the reaction delaying layers 215 and 225, tungsten (W), chromium (Cr), tantalum (Ta) or an alloy thereof may be used besides using Ti.

FIGS. 9A to 9D illustrate a eutectic metal bonding layer (EM) structure obtained through the first and second bonding metal layers illustrated in FIG. 8.

As shown in FIG. 9A, a eutectic metal bonding layer EM1 may include a mixture layer R21 including a eutectic metal formed of NiSnAu in a central region thereof, and Ti layers 215′ and 225′ positioned in the vicinity of the mixture layer R21. Residual Ti layers 215′ and 225′ may be present in a somewhat transformed manner (e.g., a warped or partially disconnected state) in the reaction process. An Ni layer 212a′ may remain between the Ti layer 215′ and the first substrate 211, and an Ni layer 222a′ may remain between the Ti layer 225′ and the second substrate 221.

In a different form, as shown in FIG. 9B, a eutectic metal bonding layer EM2 may include a first mixture layer R21 including a eutectic metal formed of NiSnAu in a central region thereof, and Ti layers 215′ and 225′ positioned in the vicinity of the first mixture layer R21. In addition, Sn may be diffused on one side, that is, the Ti layer 215′, to form a second mixture layer R22 formed of NiSnAu. In the form of bonding system as illustrated in FIG. 9B, the Ni layers 212a′ and 222′ may also remain in an interface between the first and second substrates 211 and 221.

In a different form of bonding system, as shown in FIG. 9C, a eutectic metal bonding layer EM3 may include a first mixture layer R21 including a eutectic metal formed of NiSnAu in a central region thereof, Ti layers 215′ and 225′ positioned in the vicinity of the first mixture layer R21, and second mixture layers R22 and R22′ that are formed of NiSnAu at an edge of the Ti layers 215′ and 225′, respectively. In addition, in the form of bonding system as illustrated in FIG. 9C, the Ni layers 212a′ and 222a′ may also remain in an interface between the first and second substrates 211 and 221.

In a different form of bonding system, as shown in FIG. 9D, a eutectic metal bonding layer EM4 may include a first mixture layer R21 including a eutectic metal formed of NiSnAu in a central region thereof, Ti layers 215a′ and 225a′ positioned in the vicinity of the first mixture layer R21, and second mixture layers R22 and R22′ formed of NiSnAu at an edge of the eutectic metal bonding layer EM4, on which an Ni layer barely remains due to an overall reaction of the eutectic metal bonding layer EM4 thereof.

As described above, even when the same metal bonding layer as shown in FIG. 8 is used, various forms of bonding systems, that is, eutectic metal bonding layers EM, may be provided according to a bonding process actually applied thereto as shown in FIGS. 9A to 9D. On the other hand, the bonding systems shown in FIGS. 9A to 9D may be considered to be serial processes in which reaction processes are performed in sequence as illustrated therein together with diffusion, e.g., in the order of FIGS. 9A, 9B, 9C and 9D.

In the present example, unlike the structure of the second reaction layer illustrated in FIG. 8, the Au layer and the Sn layer may be stacked in the sequence opposite thereto. Even with such a sequential change, the eutectic metal bonding layer (EM) structures shown in FIGS. 9A to 9D may be similar to each other.

A cap layer may be formed on the metal bonding layer as needed, and both sides of metal bonding layers maybe changed to have an asymmetrical structure. An example thereof is illustrated in FIG. 10.

FIG. 10 shows, as a bonding target object, first and second substrates 311 and 321 having respective surfaces on which respective first and second bonding metal layers 312 and 322 are formed.

The first bonding metal layer 312 may include a cap layer 312b formed on a first reaction layer 312a formed on one surface of the first substrate 311. The second bonding metal layer 322 may include a first reaction layer 322a formed on one surface of the second substrate 321, a second reaction layer 322c formed on the first reaction layer 322a, and a cap layer 322b formed on the second reaction layer 322c. The cap layers 312b and 322b may be adopted to prevent the first and second bonding metal layers 312 and 322 from being oxidized and may be formed of Pd or Pt. The cap layers 312b and 322b as described above may have relatively low thicknesses of several tens of Å, but are not limited thereto.

In the example as illustrated in FIG. 10, the first reaction layers 312a and 322a may be formed of Ni. In addition to, or instead of, Ni, as the first reaction layers 312a and 322a, Pt, Au, Cu or Co may be used. The second reaction layer 322c may be formed of Sn.

In the example as illustrated in FIG. 10, the reaction delaying layer 325 may be formed between the first reaction layer 322a and the second reaction layer 322c only in the second bonding metal layer 322. The reaction delaying layer 325 may be formed of Ti. W, Cr, Ta or an alloy thereof may be used in addition to, or instead of, Ti, as necessary.

FIGS. 11A to 11d illustrate a eutectic metal bonding layer (EM) structure obtained using the first and second bonding metal layers shown in FIG. 10.

As shown in FIG. 11A, mixture layers R31 and R32 may be formed in the vicinity of the reaction delaying layer, that is, a Ti layer 325′. The mixture layers R31 and R32 may be formed of NiSn containing an element of the cap layers 312b and 322b (see FIG. 10), that is, Pt or Pd. Ni layers 312a′ and 322a′ may remain in the vicinity of the mixture layers R31 and R32.

In a different form thereto, as shown in FIG. 11B, the mixture layers R31 and R32 may be formed in the vicinity of the reaction delaying layer, that is, the Ti layer 325′. The mixture layers R31 and R32 may be formed of NiSn containing an element of the cap layers 312b and 322b (see FIG. 10), that is, Pt or Pd. The eutectic metal bonding layer (EM) structure shown in FIG. 11B, i.e., the layer EM2, may be different from that of FIG. 11A, i.e., the layer EM1, in that an Ni layer barely remains at an edge of the layer EM2, due to an overall reaction of the layer EM2.

As such, even when the same metal bonding layer as shown in FIG. 10 is used, various forms of bonding systems, that is, eutectic metal bonding layers EM, may be provided according to a bonding process actually applied thereto as shown in FIGS. 11A and 11B. On the other hand, the bonding systems shown in FIGS. 11A and 11B may be considered to be serial processes in which reaction processes are performed in sequence as illustrated therein together with diffusion, e.g., in the order of FIG. 11A and FIG. 11B.

FIG. 12 shows, as a bonding target object, first and second substrates 411 and 421 having respective surfaces on which respective first and second bonding metal layers 412 and 422 are formed.

Unlike the example illustrated in FIG. 10, metal bonding layers formed on both bonding target objects may have a symmetrical structure. That is, the first bonding metal layer 412 may include a first reaction layer 412a formed on one surface of the first substrate 411, a second reaction layer 412c formed on the first reaction layer 412a, and a cap layer 412b formed on the second reaction layer 412c. In a similar manner thereto, the second bonding metal layer 422 may include a first reaction layer 422a formed on one surface of the second substrate 421, a second reaction layer 422c formed on the first reaction layer 422a, and a cap layer 422b formed on the second reaction layer 422c. The cap layers 412b and 422b may be adopted to prevent the first and second bonding metal layers 412 and 422 from being oxidized, respectively. The cap layers 412b and 422b may be formed of Pd or Pt. The cap layers 412b and 422b as described above may have relatively low thicknesses of several tens of Å, but are not limited thereto.

In the example as illustrated in FIG. 12, the first reaction layers 412a and 422a may be formed of Ni. In addition to, or instead of, Ni, as the first reaction layers 412a and 422a, Pt, Au, Cu or Co may be used. The second reaction layers 412c and 422c may be formed of Sn.

In addition, reaction delaying layers may be applied to both of the first and second bonding metal layers 412 and 422. That is, the reaction delaying layers 415 and 425 may be applied to the first and second bonding metal layers 412 and 422, respectively. The reaction delaying layers 415 and 425 may be formed of Ti. In addition to, or instead of, Ti, W, Cr, Ta or an alloy thereof may be used as necessary.

FIGS. 13A to 13C illustrate a eutectic metal bonding layer (EM) structure obtained using the first and second bonding metal layers 412 and 422 shown in FIG. 12.

As shown in FIG. 13A, a mixture layer R41 may be formed in a central region of a eutectic metal bonding layer EM1. Here, the mixture layer R41 may be formed of NiSn containing an element of the cap layers 412b and 422b, that is, platinum (Pt) or palladium (Pd). Ti layers 415′ and 425′ may remain in the vicinity of the mixture layer R41. As described above, residual Ti layers 415′ and 425′ may be present in a somewhat transformed manner (e.g., a warped or partially disconnected state) in the reaction process. An Ni layer 412a′ may remain between the Ti layer 415′ and the first substrate 411. An Ni layer 422a′ may remain between the Ti layer 425′ and the second substrate 421.

In a different form therefrom, as shown in FIG. 13B, the first mixture layer R41 including a eutectic metal formed of NiSn containing Pt or Pd may be formed. Ti layers 415′ and 425′ may be positioned in the vicinity of the first mixture layer R41. In addition, Sn may be diffused on one side, that is, the Ti layer 415′, to form a second mixture layer R42 formed of NiSn. In the form of bonding system, as illustrated in FIG. 13B, the Ni layers 412a′ and 422a′ may also remain in an interface between the first and second substrates 411 and 421.

In a different form of bonding system, as shown in FIG. 13C, the first mixture layer R41 including a eutectic metal formed of NiSn containing Pt or Pd may be formed. Ti layers 415′ and 425′ may be positioned in the vicinity of the first mixture layer R41. In addition, second mixture layers R42 and R42′ formed of NiSn containing Pt or Pd may be formed at respective edges of the Ti layers 415′ and 425′. In the case of the bonding system as illustrated in FIG. 13C, an Ni layer may only partially be formed on respective edges of the second mixture layers.

As such, even when the same metal bonding layer as shown in FIG. 12 is used, various forms of bonding systems, that is, eutectic metal bonding layers EM, may be provided according to a bonding process actually applied thereto as shown in FIGS. 13A to 13C. On the other hand, the bonding systems shown in FIGS. 13A to 13C may be considered to be serial processes in which reaction processes are performed in sequence as illustrated therein together with diffusion, e.g., in the order of FIG. 13A, FIG. 13B and FIG. 13C.

The above-mentioned various forms of bonding systems may be useful for bonding an electronic device such as a semiconductor light emitting device to a substrate. As an example, a method of manufacturing a semiconductor light emitting device using the above-described eutectic metal bonding layer is illustrated in FIGS. 14A to 14D.

FIGS. 14A to 14D are cross-sectional views illustrating exemplary steps of a method of manufacturing a semiconductor light emitting device according to another embodiment of the present inventive concept.

With reference to FIG. 14A, a light emitting laminate may be prepared by sequentially growing a first conductive semiconductor layer 702, an active layer 703, and a second conductive semiconductor layer 704, on a growth substrate, that is, a sapphire substrate 701.

Such a growth process may be performed using, for example, a metal organic chemical vapor deposition (MOCVD) or a molecular beam epitaxy (MBE). The light emitting laminate may be formed of a group III-V-based semiconductor, specifically, a group III nitride semiconductor represented by (AlxGayIn_{(1-x-y)}N (0≦x≦1, 0≦y≦1, 0≦x+y≦1). The substrate 701 for growing a nitride semiconductor crystal may be formed using sapphire, silicon carbide (SiC), silicon (Si), MgAl₂O₄, MgO, LiAlO₂ or LiGaO₂.

Subsequently, as shown in FIG. 14B, a first bonding metal layer 712 may be formed on the light emitting laminate, specifically, on the second conductive semiconductor layer 704. A second bonding metal layer 722 may be formed on a bonding surface of a permanent substrate 705.

The permanent substrate 705 may be a conductive substrate, for example, an Si substrate or an Si—Al alloy substrate. The first and second bonding metal layers 712 and 722 may include reaction delaying layers 715 and 725, respectively. The first bonding metal layer 712 may include a first reaction layer 712a and a second reaction layer 712b, which mutually react and form a eutectic metal, and the reaction delaying layer 715 may be located between the first reaction layer 712a and the second reaction layer 712b. Similarly, the second bonding metal layer 722 may include a first reaction layer 722a and a second reaction layer 722b, which mutually react and form a eutectic metal, and the reaction delaying layer 725 may be located between the first reaction layer 722a and the second reaction layer 722b.

The first reaction layers 712a and 722a are layers respectively bonding to, as the bonding target object, the permanent substrate 705 and the light emitting laminate. The first reaction layers 712a and 722a may include at least one of nickel (Ni), platinum (Pt), gold (Au), copper (Cu) and cobalt (Co). The second reaction layers 712b and 722b may include a metal selected from tin (Sn), indium (In), zinc (Zn), bismuth (Bi), gold (Au), cobalt (Co) or an alloy thereof.

The reaction delaying layers 715 and 725 may include a metal selected from titanium (Ti), tungsten (W), chromium (Cr), tantalum (Ta) or an alloy thereof. The reaction delaying layers 715 and 725 may have a thickness of 10 Å to 1000 Å.

Subsequently, the permanent substrate 705 may be disposed on the second conductive semiconductor layer 704 such that the first and second bonding metal layers 712 and 722 face each other, and heat may be applied thereto to melt the first and second bonding metal layers 712 and 722, thereby forming a eutectic metal bonding layer EM. The molten second reaction layers 712b and 722b may move to react with the first reaction layers 712a and 722a, respectively, to thereby form a eutectic metal. At this time, reaction may be delayed by the reaction delaying layers 715 and 725 adopted in the example as illustrated in FIG. 14B, to secure time sufficient for the movement thereof such that the filling may overall be enhanced.

Next, as shown in FIG. 14C, a laser beam (not shown) maybe irradiated onto an interface between the growth substrate 701 and the first conductive semiconductor layer 702 to thereby separate the growth substrate 701 therefrom.

Subsequently, as shown in FIG. 14D, a first electrode 707 may be formed on a surface of the first conductive semiconductor layer 702 exposed due to the separation of the growth substrate 701. A bonding electrode (not shown) may be further formed on a surface of the permanent substrate 705 opposite to the exposed surface of the first conductive semiconductor layer 702 as needed.

As such, when a bonding surface of the light emitting laminate or a bonding surface of the permanent substrate 705 has a step structure or a structure such as a concave-convex portion, the generation of voids may be suppressed and a solid eutectic metal bonding layer EM may be formed by appropriately filling even a relatively small space, and bonding reliability may be significantly enhanced.

Such a eutectic metal bonding layer may be usefully applied to other various semiconductor light emitting devices. FIGS. 15A and 15B are a plan view and a side cross-sectional view, respectively, illustrating another example of the semiconductor light emitting device fabricated by a method of manufacturing a semiconductor light emitting device according to an embodiment of the present inventive concept.

As illustrated in FIGS. 15A and 15B, a semiconductor light emitting device 800 may include a permanent substrate, that is, a conductive substrate 810, a first electrode layer 820, an insulating layer 830, a second electrode layer 840, a second conductive semiconductor layer 804, an active layer 803, and a first conductive semiconductor layer 802.

The first electrode layer 820 may be stacked on the conductive substrate 810 and a portion of the first electrode layer 820 may extend through a contact hole 880 penetrating the insulating layer 830, the second electrode layer 840, the second conductive semiconductor layer 804 and the active layer 803 and penetrating up to a portion of the first conductive semiconductor layer 802, so as to contact the first conductive semiconductor layer 802. Thus, the conductive substrate 810 may be electrically connected to the first conductive semiconductor layer 802.

That is, the first electrode layer 820 may electrically connect the conductive substrate 810 to the first conductive semiconductor layer 802, through the contact hole 880. More specifically, the conductive substrate 810 may be electrically connected to the first conductive semiconductor layer 802 through a region having the size of the contact hole 880, e.g., a contact region 890 (see FIG. 15A) that is an area of contact between the first electrode layer 820 and the first conductive semiconductor layer 802.

Meanwhile, the first electrode layer 820 may be provided with the insulating layer 830 formed thereon to electrically insulate the first electrode layer 820 from different layers except for the conductive substrate 810 and the first conductive semiconductor layer 802. That is, the insulating layer 830 may be provided between side portions of the second electrode layer 840, the second conductive semiconductor layer 804 and the active layer 803 exposed to the contact hole 880, and the first electrode layer 820. The insulating layer 830 may be also provided between the first electrode layer 820 and the second electrode layer 840. In addition, the insulating layer 830 may be provided with side portions of predetermined regions of the first conductive semiconductor layer 802.

The second electrode layer 840 may be provided on the insulating layer 830, but may not be formed on predetermined portions thereof through which the contact hole 880 is formed. Here, the second electrode layer 840 may have an exposed region of a portion of an interface contacting the second conductive semiconductor layer 804, that is, at least one exposed region 845 as shown in FIG. 15B. The exposed region 845 may be provided with an electrode pad part 846 formed thereon connecting the second electrode layer 840 to external power.

In addition, a light emitting laminate may not be formed on the exposed region 845. Further, the exposed region 845 may be provided at an edge of the semiconductor light emitting device 800 as shown in FIG. 15A so as to significantly increase a light emission area of the semiconductor light emitting device 800. On the other hand, the second electrode layer 840 may include any one of silver (Ag), aluminum (Al) and platinum (Pt). That is, the second electrode layer 840 electrically contacts the second conductive semiconductor layer 804. Therefore, a layer having a function able to increase light emission efficiency by reflecting light generated in the active layer 805 to thus be directed externally while significantly reducing resistance of contact of the second conductive semiconductor layer 804 may be provided, and thus, the second electrode layer 840 may be provided.

The second conductive semiconductor layer 804 may be provided on the second electrode layer 840, and the active layer 805 may be provided on the second conductive semiconductor layer 804, and the first conductive semiconductor layer 802 may be provided on the active layer 804. Here, the first conductive semiconductor layer 802 may be an n-type nitride semiconductor, and the second conductive semiconductor layer 804 may be a p-type nitride semiconductor.

As shown in FIG. 15B, the eutectic metal bonding layer EM may be formed between the conductive substrate 810 and the first metal layer 820 such that the light emitting laminate may be bonded to the conductive substrate 810.

The eutectic metal bonding layer EM may be formed of a eutectic metal resulting from a reaction between molten metal (including alloys) and may be a eutectic metal containing a metal selected from tin (Sn), indium (In), zinc (Zn), bismuth (Bi), lead (Pb), nickel (Ni), gold (Au), platinum (Pt), copper (Cu), cobalt (Co), or alloys thereof. In addition, the eutectic metal bonding layer EM may include a reaction delaying layer 815. The reaction delaying layer 815 may be formed of a metal selected from titanium (Ti), tungsten (W), chromium (Cr), tantalum (Ta) or an alloy thereof, and may have a function of delaying a reaction process in which a eutectic metal is obtained in a bonding process.

As a result, since the reaction delaying layer 815 is formed during a reaction process in which the eutectic metal is formed, the reaction delaying layer 815 may be present in a form of having a discontinuous or irregular thickness rather than having a complete layer structure.

In the embodiments illustrated in FIGS. 14A to 15B, a metal bonding layer and a eutectic metal bonding layer (a bonding system) according to various examples with reference to FIGS. 6 to 13 may be usefully used.

As set forth above, in a method of forming a metal bonding layer and a method of manufacturing a semiconductor light emitting device therewith according to embodiments of the present inventive concept, the generation of voids within a eutectic metal bonding layer obtained through a reaction of a metal bonding between both bonded objects may be effectively suppressed whereby relatively high bonding strength may be maintained. In particular, the method may be usefully applied to a transfer technology of an electronic device such as a semiconductor light emitting device. Further, the generation of voids that would easily occur in a eutectic metal bonding layer when a bonding surface is an uneven surface having a concave-convex portion or a step structure, may be significantly suppressed.

While the inventive concept has been shown and described in connection with embodiments, it will be apparent to those skilled in the art that modifications and variations could be made without departing from the spirit and scope of the present inventive concept as defined by the appended claims.

What is claimed is:

1. A method of forming a metal bonding layer, comprising:
forming a first bonding metal layer and a second bonding metal layer on surfaces of first and second bonding target objects, respectively;
disposing the second bonding target object on the first bonding target object to allow the first and second bonding metal layers to face each other; and
forming a eutectic metal bonding layer through a reaction between the first and second bonding metal layers,
wherein at least one of the first and second bonding metal layers includes a reaction delaying layer formed of a metal for delaying the reaction between the first and second bonding metal layers.

2. The method of claim 1, wherein the at least one of the first and second bonding metal layers includes a metal selected from the group consisting of tin (Sn), indium (In), zinc (Zn), bismuth (Bi), lead (Pb), nickel (Ni), gold (Au), platinum (Pt), copper (Cu), cobalt (Co), and an alloy thereof.

3. The method of claim 2, wherein the reaction delaying layer includes a metal selected from the group consisting of titanium (Ti), tungsten (W), chromium (Cr), tantalum (Ta), and an alloy thereof.

4. The method of claim 3, wherein the reaction delaying layer has a thickness of 10 Å to 1000 Å.

5. The method of claim 3, wherein:
the at least one of the first and second bonding metal layers includes a first reaction layer formed on one surface of the first or second bonding target object and containing at least one of nickel (Ni), platinum (Pt), gold (Au), copper (Cu) and cobalt (Co) and a second reaction layer formed on the first reaction layer, reacting with a metal of the first reaction layer to provide a eutectic metal, and containing a metal selected from the group consisting of tin (Sn), indium (In), zinc (Zn), bismuth (Bi), gold (Au), cobalt (Co), and an alloy thereof, and
the reaction delaying layer is disposed between the first reaction layer and the second reaction layer.

6. The method of claim 5, wherein the at least one of the first and second bonding metal layers further includes a cap layer formed on the second reaction layer and containing at least one of platinum (pt) and lead (pb).

7. The method of claim 1, wherein the surfaces of the first and second bonding target objects, on which the first bonding metal layer and the second bonding metal layer are formed, respectively, are uneven surfaces.

8. A method of manufacturing a semiconductor light emitting device, comprising:
preparing a light emitting laminate including a first conductive semiconductor layer, an active layer, and a second conductive semiconductor layer sequentially formed on a temporary substrate;
forming a first bonding metal layer on the light emitting laminate and forming a second bonding metal layer on a permanent substrate;
disposing the light emitting laminate on the permanent substrate to allow the first and second bonding metal layers to contact each other; and
forming a eutectic metal bonding layer through a reaction between the first and second bonding metal layers to bond the light emitting laminate to the permanent substrate,
wherein at least one of the first and second bonding metal layers includes a reaction delaying layer formed of a metal for delaying the reaction between the first and second bonding metal layers.

9. The method of claim 8, wherein the permanent substrate is a conductive substrate.

10. The method of claim 9, further comprising removing the temporary substrate, a semiconductor growth substrate, after the forming of the eutectic metal bonding layer

11. The method of claim 8, wherein the at least one of the first and second bonding metal layers includes a metal selected from the group consisting of tin (Sn), indium (In), zinc (Zn), bismuth (Bi), lead (Pb), nickel (Ni), gold (Au), platinum (Pt), copper (Cu), cobalt (Co), and an alloy thereof.

12. The method of claim 11, wherein the reaction delaying layer includes a metal selected from the group consisting of titanium (Ti), tungsten (W), chromium (Cr), tantalum (Ta), and an alloy thereof.

13. The method of claim 12, wherein the reaction delaying layer has a thickness of 10 Å to 1000 Å.

14. The method of claim 12, wherein the at least one of the first and second bonding metal layers includes a first reaction layer formed on one surface of the first or second bonding target object and containing at least one of nickel (Ni), platinum (Pt), gold (Au), copper (Cu) and cobalt (Co) and a second reaction layer formed on the first reaction layer, reacting with a metal of the first reaction layer to provide a eutectic metal, and containing a metal selected from the group consisting of tin (Sn), indium (In), zinc (Zn), bismuth (Bi), gold (Au), cobalt (Co), and an alloy thereof, and
the reaction delaying layer is located between the first reaction layer and the second reaction layer.

15. The method of claim 14, wherein the at least one of the first and second bonding metal layers further includes a cap layer formed on the second reaction layer and containing at least one of platinum (pt) and lead (pb).

16. A method of forming a metal bonding layer, comprising:
forming a first bonding metal layer and a second bonding metal layer on surfaces of first and second bonding target objects, respectively, the first and second bonding metal layers including first and second reaction delaying layers formed of a metal, respectively; and
forming a first mixture layer including a eutectic metal resulting from a reaction between the first and second bonding metal layers,
wherein a first residual reaction delaying layer and a second residual reaction delaying layer are positioned in a vicinity of the first mixture layer through a reaction between the first and second bonding metal layers.

17. The method of claim 16, further comprising:
forming a second mixture layer at an edge of the first residual reaction delaying layer; and
forming a third mixture layer at an edge of the second residual reaction delaying layer.

18. The method of claim 16, wherein the eutectic metal is formed of NiSn or NiSnAu.

19. The method of claim 16, wherein the reaction delaying layer includes a metal selected from the group consisting of titanium (Ti), tungsten (W), chromium (Cr), tantalum (Ta), and an alloy thereof.

20. The method of claim 16, wherein:
the first and second residual reaction delaying layers are formed of a same material as a material of the reaction delaying layer; and
the first and second residual reaction delaying layers are warped or partially disconnected.
